(19) United States
(12) Patent Application Publication
(10) Pub. No.: US 2023/0249609 A1
(43) Pub. Date: Aug. 10, 2023

(54) VEHICLE HEADLIGHT DEVICE

(71) Applicant: HONDA MOTOR CO., LTD., Tokyo (JP)

(72) Inventors: Masayoshi TAKORI, Saitama (JP); Yuji TSUCHIYA, Saitama (JP)

(21) Appl. No.: 18/165,337

(22) Filed: Feb. 7, 2023

(30) Foreign Application Priority Data
Feb. 8, 2022 (JP) 2022-018298

(51) Int. Cl. B60Q 1/08

(52) U.S. Cl. CPC B60Q 1/085; B60Q 2300/112; B60Q 2300/05

(57) ABSTRACT

A vehicle headlight device is provided which can improve overlooking of pedestrians by a driver, even under adverse conditions such as nighttime or rain at night. The vehicle headlight device includes a photoirradiator which irradiates light in a light distribution region of the vehicle in an irradiation pattern in which a bright region and dark region are alternately repeated, in which the photoirradiator irradiates an irradiation pattern so as to flow along the travel direction of the vehicle. In this state, the photoirradiator includes a converter which changes a velocity at which flowing the irradiation pattern according to the vehicle speed of the vehicle, and the converter causes the velocity at which scenery viewed from the vehicle flows and the velocity at which flowing the irradiation pattern to match according to vehicle speed.

This application is based on and claims the benefit of priority from Japanese Patent Application No. 2022-018298, filed on 8 Feb. 2022, the content of which is incorporated herein by reference.

### BACKGROUND OF THE INVENTION

### Field of the Invention

The present invention relates to a vehicle headlight device.

### Related Art

As a vehicle headlight device, a device has been proposed whereby a driver can visually check for pedestrians well, while suppressing dazing of pedestrians (for example, refer to Patent Document 1). The vehicle headlight device of Patent Document 1 configures so as to reduce the illumination amount on the upper body of pedestrians according to the distance to the pedestrian acquired from a pedestrian detection sensor.
Patent Document 1: Japanese Unexamined Patent Application, Publication No. 2013-184614

### SUMMARY OF THE INVENTION

However, there is a tendency for accidents increasing due to overlooking a pedestrian in front of a vehicle in a straight road. Although it should be made such overlooking of pedestrians does not occur, the existing vehicle headlight devices are not sufficient means under adverse conditions such as nighttime or rain at night in particular.

The present invention has been made taking account of the above such situation, and has an object of providing a vehicle headlight device which can improve overlooking of pedestrians by a driver even under adverse conditions such as nighttime or rain at night.

According to a first aspect of the present invention, a vehicle headlight device (for example, the vehicle headlight device 1 described later) includes: a photoirradiator (for example, pattern irradiation lamp 4 described later) which irradiates light in a light distribution region (for example, the pattern irradiation light distribution region 16 described later) of a vehicle (for example, the vehicle 2 described later) in an irradiation pattern (for example, the irradiation pattern Pf described later) in which a bright region (for example, the bright region a1 described later) and a dark region (for example, the dark region a2 described later) are alternately repeated, in which the photoirradiator irradiates so as to flow the irradiation pattern along a travel direction of the vehicle.

According to a second aspect of the present invention, in the vehicle headlight described as described in the first aspect, the photoirradiator includes a converter (for example, the converter 42 described later) which changes a velocity (for example, the velocity in the flow velocity signal Fvs described later) at which flowing the irradiation pattern according to vehicle speed (for example, the vehicle speed in the vehicle speed signal Vss described later) of the vehicle.

According to a third aspect of the present invention, in the vehicle headlight device as described in the second aspect, the converter causes a velocity at which scenery viewed from the vehicle flows and a velocity at which flowing the irradiation pattern to match according to the vehicle speed.

With the vehicle headlight device according to the first aspect, in the case of the irradiation pattern in which the bright region and dark regain are alternately repeated becoming static, it is difficult to recognize a pedestrian moving synchronously with movement of the vehicle, and thus by irradiating so as to flow this irradiation pattern along the travel direction of the vehicle, the presence of a pedestrian during movement is easily recognized from the driver. It is possible to improve overlooking of pedestrians by a driver, even under adverse conditions such as nighttime or rain at night.

With the vehicle headlight device according to the second aspect, the velocity at which flowing the irradiation pattern is appropriately changed according to vehicle speed, and the presence of the pedestrian during movement is much more reliably recognized from the driver.

With the vehicle headlight device according to the third aspect, since the velocity at which scenery viewed from the vehicle flows and the velocity at which the irradiation pattern flows thereby match, the flow of scenery viewed from the vehicle and the flow of the irradiation pattern synchronize, whereby the driver can recognize the presence of the pedestrian more easily.

### BRIEF DESCRIPTION OF THE DRAWINGS

FIG. 1 is a schematic diagram shows a vehicle headlight device as an embodiment of the present invention;

FIG. 2 is a conceptual block diagram of a pattern irradiation lamp of the vehicle headlight device in FIG. 1;

FIG. 3 is a view schematically showing a visual property of a person related to a technical concept of the present invention;

FIG. 4 is a schematic diagram in a plan view showing a light distribution area of the vehicle headlight device of an embodiment of the present invention;

FIG. 5 is a schematic diagram showing an aspect of a driving field of vision at night in the vehicle equipped with the vehicle headlight device as an embodiment of the present invention;

FIG. 6 is a view showing an aspect of a moving pedestrian being illuminated by the illumination pattern light of the vehicle headlight device as an embodiment of the present invention;

FIG. 7 is a view showing an aspect of a pedestrian moving toward a roadway being illuminated by the illumination pattern light of a vehicle headlight device unrelated to the present invention from the viewpoint of a driver; and

FIG. 8 is a view for explaining the reason for the phenomenon of FIG. 7 occurring.

### DETAILED DESCRIPTION OF THE INVENTION

Hereinafter, an embodiment of the present invention will be explained while referencing the drawings. It should be noted that light distribution area in the following explanation is the irradiation area of light, and irradiation pattern is an irradiation shape of light in the light distribution area.

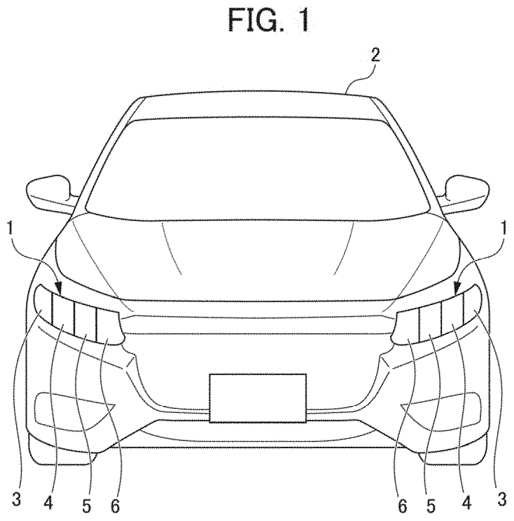

FIG. 1 is a schematic diagram showing a vehicle headlight device 1 of an embodiment of the present invention. The vehicle headlight device 1 is respectively equipped at the left side and right side in a form left/right symmetrical viewing from a central position in the vehicle width direction of a vehicle 2. In order from an outer side in the vehicle-width direction towards the inner side, a turn signal lamp 3, pattern irradiation lamp 4, low beam lamp 5 and high beam lamp 6 are arranged in the vehicle headlight device 1.

The turn signal lamp 3 is a normal lamp of this type. In an irradiation pattern in which a bright area and dark area are alternately repeated, the pattern irradiation lamp 4 irradiates this irradiation pattern so as to flow along the travel direction of the vehicle. The low beam lamp 5 irradiates light in a predetermined light distribution area of a low beam. The high beam lamp 6 irradiates light in a predetermined light distribution area of a high beam. It should be noted that the vehicle 2 equipped with the vehicle headlight device 1 is abbreviated as one's own vehicle 2 as appropriate hereinafter.

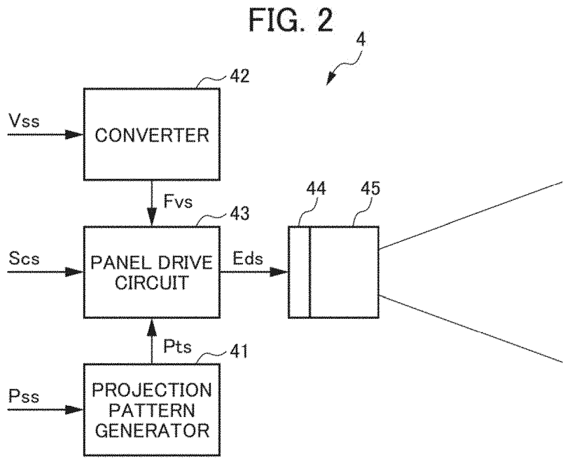

FIG. 2 is a conceptual block diagram of the pattern irradiation lamp 4 in the vehicle headlight device of FIG. 1. The pattern irradiation lamp 4 is configured to include a projection pattern generator 41, converter 42, panel drive circuit 43, light modulator 44 and projection optical system 45. It should be noted that, in practice, the panel drive circuit 43 and light modulator 44 are thermally insulated by being arranged to be separated, and these two are linked by a harness. The projection pattern generator 41 generates an irradiation pattern signal Pts expressing an irradiation pattern in which a bright area and dark area of a shape defined by a pattern selection signal Pss supplied from a lamp control ECU (not shown) equipped to the vehicle 2 are alternately repeated. The converter 42 generates a flow velocity signal Fvs defining the flow velocity when flowing the irradiation pattern from a back side to a near side ahead of the vehicle, based on the vehicle speed signal Vss supplied from the lamp control ECU.

The panel drive circuit 43 starts up according to a startup command signal Scs supplied from the lamp control ECU, and drives the light modulator 44 by emitting an element drive signal Eds for flowing the irradiation pattern in which a bright area and dark area defined by the irradiation pattern signal Pts emitted by the projection pattern generator 41 are alternately repeated, at the velocity defined by the flow velocity signal Fvs. The light modulator 44 thereby irradiates so as to flow the irradiation pattern along the travel direction of the vehicle 2 in the pattern irradiation light distribution area 16 described later through the projection optical system 45. The converter 42 supplies the flow velocity signal Fvs to the panel drive circuit 43 according to a vehicle speed signal Vss expressing the vehicle speed of the vehicle 2, and makes the velocity at which scenery viewed from the vehicle 2 flows, and the velocity at which flowing the irradiation pattern Pf match.

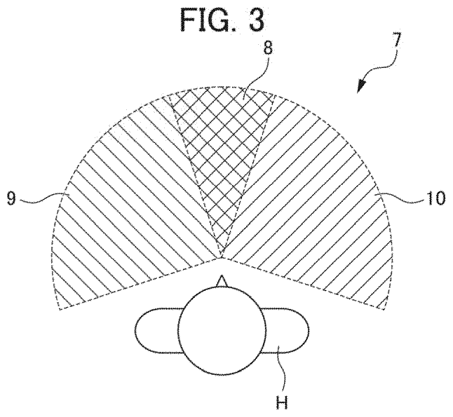

FIG. 3 is a view schematically showing the visual property of a person related to a technical concept of the vehicle headlight device 1 of the present invention described later. In FIG. 3, a forward field of view 7 of a person H is divided into a center field of view 8 which widens at a fixed acute angle to the left and right from a front face, and a left peripheral field of view 9 and right peripheral field of view 10 adjacent on the left and right of the center field of view 8, from the visual property of the person.

The general visual property of a person exhibits a tendency whereby shapes are clearly visible but reaction to movement is delayed, in the center field of view 8. The left peripheral field of view 9 and right peripheral field of view 10 exhibit a tendency whereby shapes are vague, but reaction to movement is fast, i.e. sensitivity to motion is high. The vehicle headlight device 1 of the present invention is based on the idea of actively using the aforementioned such visual property of a person.

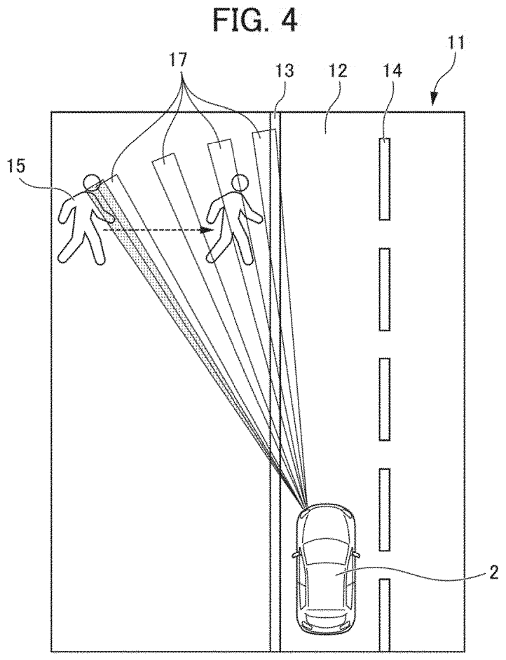

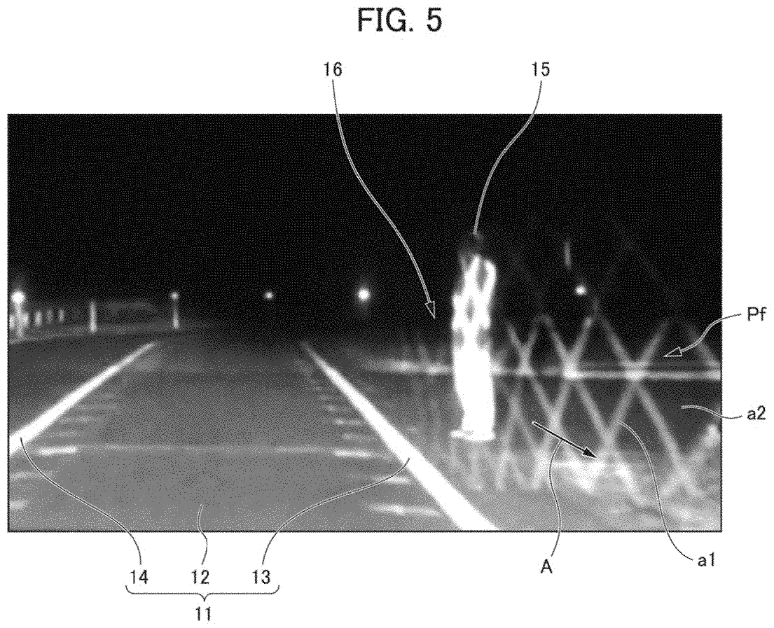

FIG. 4 is a schematic diagram showing a light distribution area of the vehicle headlight device 1 in a plan view. FIG. 5 is a schematic diagram showing an aspect of a driving field of view at nighttime of the vehicle (one's own vehicle 2) equipped with the vehicle headlight device 1 of an embodiment of the present invention. On the road 11, a divider line 13 and divider line 14 are drawn at both sides of the travel lane 12 of one's own vehicle. A situation is assumed in which a pedestrian 15 stays on a side of the travel lane 12 of one's own vehicle 2 of the road 11.

The inventors, etc. have already proposed technology which quickly captures the presence of a pedestrian 15, by irradiating light from the vehicle headlight device 1 in a stripe-like or grid-like irradiation pattern in which a bright area and dark area are alternately repeated. When irradiating light in the aforementioned such irradiation pattern, the presence of the pedestrian 15 is obviously recognized in the peripheral field of view (left-peripheral field of view 9, right-peripheral field of view 10) in which sensitivity to motion is high with the visual performance of the driver.

The inventors, etc. further obtained knowledge in the course of repeating experiments that, in the case of the pedestrian 15 moving, there is a problem in that the bright region and dark region do not relatively move within the silhouette of the pedestrian 15, and a phenomenon occurs whereby the driver is hardly aware of the pedestrian 15. The present invention addresses this problem, and tries to solve by irradiating the irradiation pattern Pf in a mode flowing from the back side toward the near side ahead of the vehicle 2.

In FIGS. 4 and 5, the pattern irradiation lamp 4 (FIG. 1) of the vehicle headlight device 1 irradiates with the irradiation light 17 the pattern irradiation light distribution area 16 set so as to extend forwards from one's own vehicle 2 on a side of the travel lane 12 of one's own vehicle. The irradiation light 17 has an irradiation pattern Pf in which a bright region a1 and dark region 2a are alternately repeated. The irradiation pattern Pf is irradiated in a mode flowing in the direction of the arrow A in FIG. 5 from the back side to the near side ahead of one's own vehicle 2.

The irradiation of the irradiation pattern Pf in such a mode is realized by the light modulator 44 in FIG. 2 being driven by the element drive signal Eds. In other words, the irradiation pattern defined by the irradiation pattern signal Pts produced by the projection pattern generator 41 flows at the flow velocity defined by the flow velocity signal Fvs supplied from the converter 42. The panel drive circuit 43 drives the light modulator 44 by generating the element drive signal Eds causing the flow of such an irradiation pattern.

The pedestrian 15 moving in the pattern irradiation light distribution region 16 is irradiated in a mode in which the irradiation pattern in which the bright region a1 and dark region a2 are alternately repeated flows from the back side toward the near side ahead of the vehicle 2, by the irradiation light 17 of the pattern irradiation lamp 4.

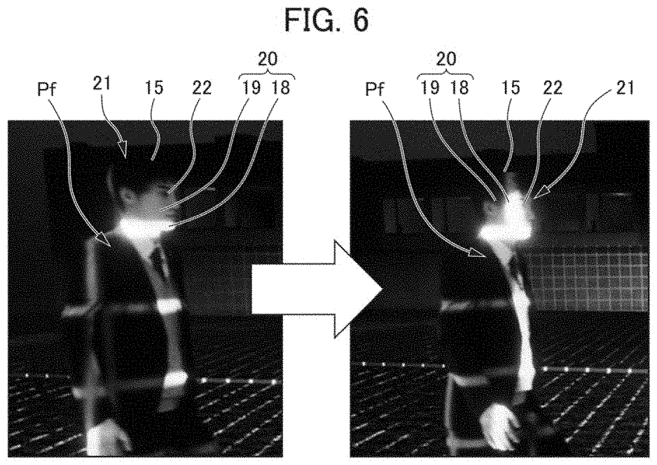

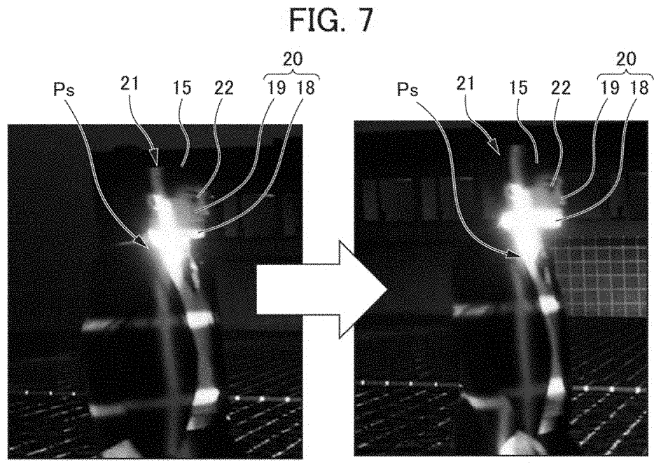

Even if the irradiation pattern in which the bright region and dark region are alternately repeated, if the irradiation light having an irradiation pattern which is stationary, in the case of the pedestrian 15 moving, the bright region and dark region do not move relatively within the silhouette of the pedestrian 15, and the driver is hardly aware of the pedestrian 15. However, according to the flowing irradiation pattern, even if the pedestrian 15 is moving, since the bright region and dark region move relatively in relation to the pedestrian 15, it is possible for the driver to easily be aware of the presence of the pedestrian 15. This phenomenon will be explained next by referencing FIGS. 6 and 7.

FIG. 6 is a view showing an aspect in which the pedestrian 15 during movement is irradiated by light of a state in which the irradiation pattern Pf from the pattern irradiation lamp 4 in the vehicle headlight device 1 according to the embodiment of the present invention flows from the back side toward the near side ahead of the vehicle 2, in the viewpoint of the driver. FIG. 7 is a view not according to the present invention, showing an aspect of the pedestrian 15 during movement being irradiated by light of a mode in which the irradiation pattern Ps is not flowed, in the viewpoint of the driver.

In the case of the flowing irradiation pattern Pf of FIG. 6, the lattice pattern 20 from a bright part 18 which is a portion in which the pedestrian 15 during movement is brightly lit by the light of the bright region, and a dark part 19 which is a dark portion not lit corresponding to the dark region, moves within the silhouette 21 of the pedestrian 15. For this reason, the degree of visual stimulus on the side of the driver relative to reflected light from the pedestrian 15 is very remarkable.

In addition, the lattice pattern 20 moves within the silhouette 21 of the pedestrian 15, and the bright part 18 repeatedly crosses the eye 22 of the pedestrian 15. For this reason, the pedestrian 15 receives stimulus from the flickering of light, and obviously recognizes the presence of the vehicle 2. Therefore, it is possible to improve overlooking of the pedestrian 15 by the driver even under adverse conditions such as nighttime or rain at night, and possible for the pedestrian 15 to be quickly aware of the approach of the vehicle 2.

In contrast, in the case of irradiating the pedestrian 15 during movement with light of a state in which the irradiation pattern Ps is not flowing, unrelated to the present invention in FIG. 7, the lattice pattern 20 by the bright part 18 and dark part 19 does not move within the silhouette 21 of the pedestrian 15. For this reason, the degree of visual stimulus on the driver side relative to reflected light from the pedestrian 15 is low, and discovery of the pedestrian 15 may be delayed.

In addition, the lattice pattern 20 does not move within the silhouette 21 of the pedestrian 15, and the dark part 19 may continue to remain at a position of the eye 22 of the pedestrian 15. For this reason, the pedestrian 15 does not receive stimulus from the flickering of light, and is hardly aware of the existence of the vehicle 2.

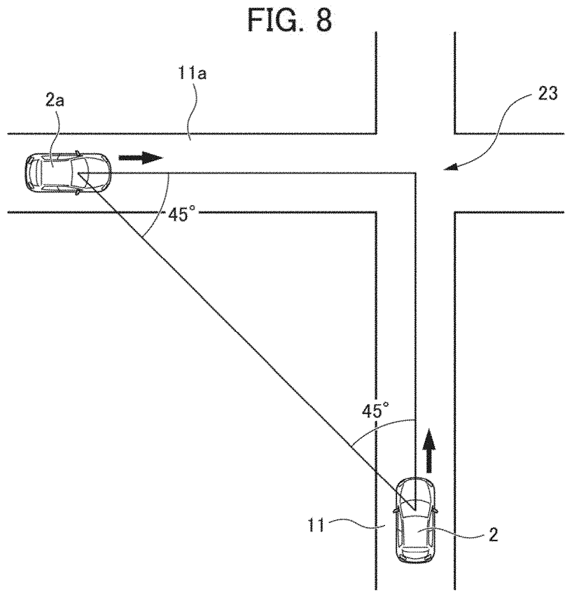

FIG. 8 is a view for explaining the reason for which the phenomenon such as in FIG. 7 occurs. In the case of irradiating the pedestrian 15 during movement with light of a state in which the irradiation pattern Ps does not flow as explained by referencing FIG. 7, the phenomenon in which the lattice pattern 20 from the bright part 18 and dark part 19 do not move within the silhouette 21 of the pedestrian 15 is considered to be due to a phenomenon similar to the so-called collision course phenomenon. The collision course phenomenon occurs at an intersection 23 having good visibility as in FIG. 8. There is a possibility of the vehicle 2 travelling on a road 11 and a vehicle 2a travelling on a road 11a towards the intersection 23 between the road 11 and road 11a colliding if continuing travel as is.

However, due to always viewing the direction of the same angle as viewing the vehicle 2a from the vehicle 2 (45 degrees in case of FIG. 8), an illusion of being stopped occurs, and this phenomenon is called the collision course phenomenon. In particular, since there is a characteristic of the peripheral field of view of a human hardly recognizing non-moving subjects, if the collision course phenomenon occurs and the other vehicle remaining in the peripheral field of view, there is also a possibility of not being able to recognize each other until entering the intersection 23.

When considering such a collision course phenomenon, a phenomenon similar thereto is considered to occur for the lattice pattern 20 of the irradiation pattern Ps from the irradiation light 17 relative to the pedestrian 15 in FIG. 7. In other words, if the pedestrian 15 comes to a stop, the lattice pattern 20 of the irradiation pattern Ps relatively displaces within the same irradiation area accompanying movement of the vehicle 2. However, if the pedestrian 15 is moving, the aforementioned such relative displacement of the lattice pattern 20 within the silhouette 21 of the pedestrian 15 and the displacement of the silhouette 21 itself of the pedestrian 15 are synchronized, and it is considered to seem like the lattice pattern 20 stopped. In contrast, when irradiating the pedestrian 15 during movement with the light in a state flowing from the back side toward the near side ahead of the vehicle 2 as in the irradiation pattern Pf of the pattern irradiation lamp 4, synchronization between the aforementioned such relative displacement of the lattice pattern 20 within the silhouette 21 of the pedestrian 15 and the displacement of the silhouette 21 itself of the pedestrian 15 can be avoided, and the problem such as that explained referencing FIG. 7 is overcome.

The configuration of the pattern irradiation lamp 4 in the vehicle headlight device 1 of the embodiment of the present invention is not limited to the embodiment in FIG. 2. For example, although configured so as to flow the irradiation pattern Pf by driving the light modulator 44 according to the element drive signal Eds from the panel drive circuit 43 of the pattern irradiation lamp 4, this configuration can adopt another mode. In other words, by driving a DMD (Digital Mirror Device) containing a micro mirror group according to a signal resembling the element drive signal Eds, the pattern irradiation lamp 4 may be configured as a projector of a state flowing the irradiation pattern Pf from the back side toward the near side ahead of the vehicle 2.

According to the vehicle headlight device 1 of the present embodiment, the following effects are exerted.

(1) The vehicle headlight device 1 includes the pattern irradiation lamp 4 as a light irradiation unit that irradiates light onto the pattern irradiation light distribution region 16 of the vehicle 2 in the irradiation pattern Pf in which the bright region a1 and dark region a2 are alternately repeated, in which the pattern irradiation lamp 4 irradiates so as to flow the irradiation pattern Pf in the travel direction of the vehicle 2. The presence of the pedestrian 15 during movement is thereby easily recognized from the driver, without depending on the walking speed of the pedestrian 15. Under adverse conditions such as nighttime or rain at night, it is possible to improve overlooking of the pedestrian 15 by the driver. In addition, also for the pedestrian, it is possible to quickly notice the presence of the vehicle 2, by configuring so that the irradiation light enters the eye.

(2) In the vehicle headlight device 1, the pattern irradiation lamp 4 includes the converter 42 which changes the velocity at which flowing the irradiation Pf according to the vehicle speed of the vehicle 2. The velocity at which flowing the irradiation pattern Pf is thereby appropriately changed according to vehicle speed, and the presence of the pedestrian 15 during movement is much more reliably recognized from the driver of the vehicle 2.

(3) With the vehicle headlight device 1, the converter 42 makes the velocity at which the scenery viewed from the vehicle 2 flows and the velocity at which flowing the irradiation pattern Pf match according to the vehicle speed of the vehicle 2. Since the velocity at which scenery viewed from the vehicle 2 flows and the velocity at which the irradiation pattern Pf flows thereby match, the flow of scenery viewed from the vehicle 2 and the flow of the irradiation pattern synchronize, whereby the driver of the vehicle 2 can recognize the presence of the pedestrian 15 more easily.

Although an embodiment of the present invention has been explained above, the present invention is not to be limited thereto. The configurations of detailed parts may be modified where appropriate within the scope of the gist of the present invention. For example, in the embodiment of FIG. 2, although configured so as to flow the irradiation pattern Pf by driving the light modulator 44 according to the element drive signal Eds from the panel drive circuit 43 of the pattern irradiation lamp 4, this configuration can adopt another mode. In other words, the pattern irradiation lamp 4 may be configured as a projector of a state flowing the irradiation pattern Pf from the back side toward the near side ahead of the vehicle 2, by driving a DMD (Digital Mirror Device) containing a micro mirror group according to a signal similar to the element drive signal Eds.

### EXPLANATION OF REFERENCE NUMERALS

a1 bright region
a2 dark region
H person
Pf, Ps irradiation pattern
Pss pattern selection signal
Pts irradiation pattern signal
Vss vehicle speed signal
Scs startup command signal
Fvs flow velocity signal
Eds element drive signal
1 vehicle headlight device
2 vehicle
3 turn signal lamp
4 pattern irradiation lamp
5 low beam lamp
6 high beam lamp
7 forward field of view
8 center field of view
9 left-peripheral field of view
10 right-peripheral field of view
11, 11a road
12 travel lane of one's own vehicle
13 divider line
14 divider line
15 pedestrian
16 pattern irradiation light distribution region
17 irradiation light
18 bright part
19 dark part
20 lattice pattern
21 silhouette
22 eye
23 intersection
41 projection pattern generator
42 converter
43 panel drive circuit
44 light modulator
45 projection optical system

What is claimed is:

1. A vehicle headlight device comprising a photoirradiator which irradiates light in a light distribution region of a vehicle in an irradiation pattern in which a bright region and a dark region are alternately repeated,
wherein the photoirradiator irradiates so as to flow the irradiation pattern along a travel direction of the vehicle.

2. The vehicle headlight device according to claim 1, wherein the photoirradiator includes a converter which changes a velocity at which flowing the irradiation pattern according to vehicle speed of the vehicle.

3. The vehicle headlight device according to claim 2, wherein the converter causes a velocity at which scenery viewed from the vehicle flows and a velocity at which flowing the irradiation pattern to match according to the vehicle speed.
